(19) United States
(12) Patent Application Publication
(10) Pub. No.: US 2010/0239210 A1
(43) Pub. Date: Sep. 23, 2010

(54) Multipurpose Telecommunications Modules

(76) Inventors: George I. Wakileh, Batavia, IL (US); Eduardo Leon, Woodridge, IL (US); Simon Shen-Meng Chen, Palatine, IL (US); Bryan D. Simmons, North Aurora, IL (US)

Correspondence Address: HARNESS, DICKEY, & PIERCE, P.L.C, 7700 Bonhomme, Suite 400, ST. LOUIS, MO, 63105, US

(21) Appl. No.: 12/728,742

(22) Filed: Mar. 22, 2010

Related U.S. Application Data
(60) Provisional application No. 61/162,166, filed on Mar. 20, 2009.

(51) Int. Cl. G02B 6/38; H05K 7/00

(52) U.S. Cl. 385/55; 361/747

(57) ABSTRACT

A telecommunications module for mounting to a docking base having at least one bay adapted for receiving a module is disclosed. The module includes a housing having a front portion, a rear portion, a bottom portion, a top portion, and two side portions. The housing includes a rear wall located at the rear portion of the housing and a bottom wall substantially perpendicular to the rear wall located at the bottom portion of the housing. The housing is sized to fit in the bay of the docking base and adapted for having at least one telecommunications component coupled to the housing. The housing includes at least one wire management device, at least one port for allowing wire to pass through the housing, and at least one connector for removably coupling the module to the docking base. A telecommunications module kit, a modular telecommunications system and a telecommunications pedestal including a telecommunications module are disclosed.

### CROSS-REFERENCE TO RELATED APPLICATIONS

This application claims the benefit of U.S. Provisional Application No. 61/162,166, filed on Mar. 20, 2009. The entire disclosure of the above application is incorporated herein by reference.

### FIELD

The present disclosure relates to multipurpose telecommunications modules.

### BACKGROUND

This section provides background information related to the present disclosure which is not necessarily prior art.

Telecommunications enclosures are commonly used in telecommunications networks to distribute telecommunications services, such as television, telephone, internet, etc. The telecommunications enclosures often contain connections between wires (e.g., fiber optic cables, copper wire, etc.) and equipment for distribution of the telecommunications network (e.g., fiber optic, copper, or other). Assorted telecommunications components, distribution components, etc. is often mounted in a telecommunications enclosure. Such components (e.g., splitters, splice trays, power supplies, batteries, etc.) are often mounted in a telecommunications enclosure by being attached by various methods to a mounting plate. Often a telecommunications enclosure (or part of a telecommunications enclosure) must be specifically manufactured to receive the particular component (e.g., to receive a particular type of fiber optic splitter, to receive copper wire splice trays, etc.)

### SUMMARY

This section provides a general summary of the disclosure, and is not a comprehensive disclosure of its full scope or all of its features.

According to one aspect of the present disclosure, a telecommunications module is disclosed for mounting to a docking base having at least one bay, the bay adapted for receiving a module. The module includes a housing having a front portion, a rear portion, a bottom portion, a top portion, and two side portions. The housing includes a rear wall located at the rear portion of the housing and a bottom wall substantially perpendicular to the rear wall located at the bottom portion of the housing. The housing is sized to fit in the bay of the docking base and adapted for having at least one telecommunications component coupled to the housing. The housing includes at least one wire management device, at least one port for allowing wire to pass through the housing, and at least one connector for removably coupling the module to the docking base.

According to another aspect, a telecommunications pedestal includes a pedestal mounting plate for receiving telecommunications distribution components, a docking base coupled to the mounting plate, and a telecommunications module removably coupled to the docking base. The docking base has at least one bay. The bay is adapted for receiving a telecommunications module. The module has a housing and at least one wire management device coupled to the housing. The housing is sized to fit in the bay of the docking base and adapted for having at least one telecommunications component coupled to the housing. The housing includes at least one port for allowing wire to pass through the housing, and at least one connector for removably coupling the module to the docking base.

According to yet another aspect of the present disclosure, a modular telecommunications system includes a housing for mounting a docking base to and a docking base mounted to the front of the housing. The housing has a front, a back and four sides defining an interior space. The back of the housing is configured for attachment to a generally flat surface. The housing includes at least one port for passing telecommunications wire between an exterior of the housing and the interior space. The docking base includes at least one bay. The bay is oriented away from the interior space of the housing when the docking base is mounted on the housing. The docking base includes at least one docking port to permit wire to pass between the interior space and the bay. Each bay is adapted to receive a telecommunications module.

According to another aspect of the present disclosure, a telecommunications module kit for assembly by a user includes a telecommunications module for removable coupling to a docking base. The module has a housing and at least one wire management device coupled to the housing. The housing is sized to fit in the bay of the docking base and adapted for having at least one telecommunications component coupled to the housing. The housing includes at least one port for allowing wire to pass through the housing, and at least one connector for removably coupling the module to the docking base. The kit also includes a telecommunications component for coupling to the module housing.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is an isometric view of a housing for a telecommunications module.

FIG. 2 is an isometric view of the other side of the housing in FIG. 1.

FIG. 3 is an isometric view of a telecommunications module including the housing in FIG. 1.

FIG. 4 is an isometric view of another housing for a telecommunications module.

FIG. 5 is an isometric view of the other side of the housing in FIG. 8.

FIG. 6 is an isometric view of a telecommunications module including the housing in FIG. 5.

FIG. 7 is an isometric view of the other side of the telecommunications module of FIG. 6.

FIG. 8 is a see-thru side view of the telecommunications module of FIG. 6.

FIG. 9 is an isometric view of a housing for a telecommunications module.

FIG. 10 is an isometric view of the other side of the housing in FIG. 9.

FIG. 11 is an isometric view of a cover for the housing in FIG. 9.

FIG. 12 is a modular telecommunications system including a module and a docking base including four bays.

FIG. 13 is the system of claim 12 with the module being mounted in a bay of the docking base.

FIG. 14 is the system of claim 12 with the module mounted and in a bay of the docking base.

FIG. 15 is a modular telecommunications system including three modules and a docking base having three bays to which the modules are mounted.

FIG. 16 is an isometric view of the system in FIG. 15 with the cover of one of the modules opened.

FIG. 17 is a front view of the system in FIG. 15 with one of the modules removed from the docking base.

FIG. 18 is a front isometric view of a modular telecommunications system including two modules and a docking base having two bays to which the modules are mounted.

FIG. 19 is a rear isometric view of the system in FIG. 18.

FIG. 20 is a front isometric view of the docking base in FIG. 18

FIG. 21 is an isometric view of a modular telecommunications system including a docking base having multiple bays and a module mounted to one of the bays.

FIG. 22 is a rear isometric view of the system in FIG. 21.

FIG. 23 is a front isometric view of the docking base in FIG. 21.

FIG. 24 is a rear isometric view of the docking base in FIG. 21 without a radius limiting spool.

FIG. 25 is an isometric view of a rear cover of the docking base in FIG. 38.

FIG. 26 is an isometric view of covers for covering ports in the docking base in FIG. 21.

FIG. 27 is an isometric view of a pedestal including a modular telecommunications system mounted thereon.

FIG. 28 is an isometric view of the pedestal in FIG. 27 with a pedestal cover installed.

FIG. 29 is an isometric front view of a pedestal including a single module installed thereon.

FIG. 30 is a close-up view of part of the pedestal in FIG. 29 with the module cover open.

FIG. 31 is an isometric front view of part of a pedestal including a docking base with a module mounted thereon.

FIG. 32 is a close-up view of the docking base and module in FIG. 31.

FIG. 33 is a view of system including a docking base, a mounting plate and a module.

FIG. 34 is a view of the system in FIG. 33 with the docking base and module removed from the mounting plate.

FIG. 35 is a view of the rear of the docking base and module in FIG. 33, with the rear cover of the docking base removed.

FIG. 36 is a telecommunications module housing a battery assembly.

### DETAILED DESCRIPTION

Example embodiments will now be described more fully with reference to the accompanying drawings.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a”, “an” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on”, “engaged to”, “connected to” or “coupled to” another element or layer, it may be directly on, engaged, connected or coupled to the other element or layer, or intervening elements or layers may be present. In contrast, when an element is referred to as being “directly on,” “directly engaged to”, “directly connected to” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath”, “below”, “lower”, “above”, “upper”, “front, “rear” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

According to one aspect of the present disclosure, a telecommunications module for mounting to a docking base includes a housing having a front portion, a rear portion, a bottom portion, a top portion, and two side portions. The docking base has at least one bay adapted for receiving said module or a like module. The housing includes a rear wall located at the rear portion of the housing and a bottom wall substantially perpendicular to the rear wall located at the bottom portion of the housing. The housing is sized to fit in the bay of the docking base and adapted for having at least one telecommunications component coupled to the housing. The housing includes at least one wire management device, at least one port for allowing wire to pass through the housing, and at least one connector for removably coupling the module to the docking base.

The telecommunications component may be any component that will physically fit in the module. Suitable telecommunications components include fiber optic connection components, copper wire connection components (including copper wire terminal blocks), power supplies, battery backups, optical to electrical transmission devices, optical splicing/connection devices, power over Ethernet devices, copper transmission devices, modems (wired and/or wireless), active electronics, optical network terminals, etc.

In one example, the telecommunications component is an optical fiber connector, sometimes referred to as an opti-tap. In such example, the housing may include a mounting hole or other mount for receiving the optical fiber connector. The housing may also be constructed to retain the optical fiber connector in the mounting hole with a first part of the optical fiber connecter inside the housing and a second part of the optical fiber connector outside the housing. Such a construction may permit a user to connect and/or disconnect fiber optic cable to the optical fiber connector from an external side of the module housing.

The telecommunications module may include a side wall substantially perpendicular to the bottom wall and the rear wall. The side wall may be approximately centered between the two side portions (e.g., in the middle of the housing, etc.) or may be located at or near one of the two side portions. When the side wall is located approximately centered between the two side portions, the side wall divides the housing into two substantially equal sized chambers.

The wire management device may be coupled to the rear wall of the module. Alternatively, or additionally, when the telecommunications module includes a side wall, the wire management device may be coupled to the side wall. The wire management device may be monolithically formed with the side wall and/or rear wall or may be a separate wire management device attached to the side wall and/or rear wall.

The wire management device may be any suitable wire management device that will fit within the housing. The wire management device may be used for managing any suitable type of telecommunications wire (e.g., power wire, copper wire, fiber optic cable, fiber optic tails, etc.) For example, the wire management device may be a radius limiting spool for storing and routing fiber optic cable without bending the cable in too tight a radius. Additionally, or alternatively, the wire management device may be a half moon device, wire and/or cable clips, wire and/or cable guides, etc.

The telecommunications module may include a cover coupled to the housing. The cover and the housing, or part of the housing, may define an interior space of the module. The cover, in combination with at least part of the housing may create a weather tight interior space of the module.

In one example, a cover is connected to the housing by a hinge permitting the cover to be pivotally moved relative to the housing. The hinge may be monolithically formed with the housing and/or the cover, or may be a separate hinge coupled to the housing and the cover. Alternatively, the cover may be coupled to the housing by any other suitable type of coupling. For example, the cover may be coupled by a screws, removable fasteners, etc.

The connector may be any suitable connector for removably coupling the module to the docking base. For example, the connector may be an L-shaped protrusion from the rear wall for mating with an opening in a docking base. The connector may be monolithically formed with the housing or may be a separate connector coupled to the housing.

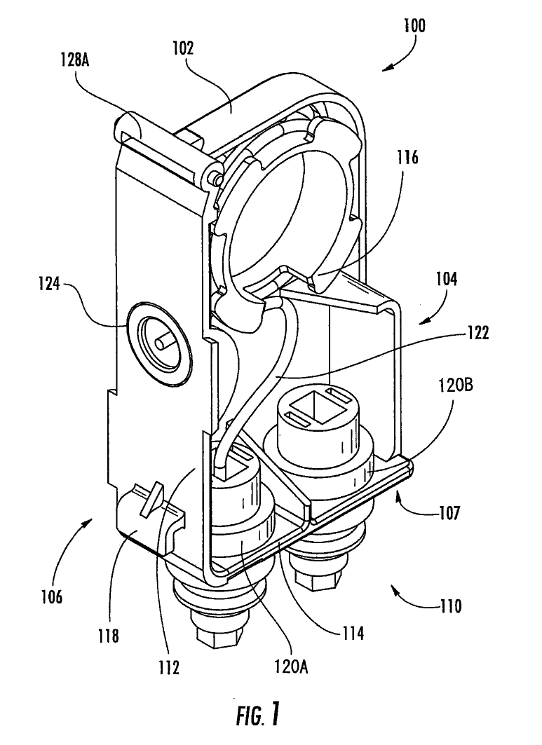

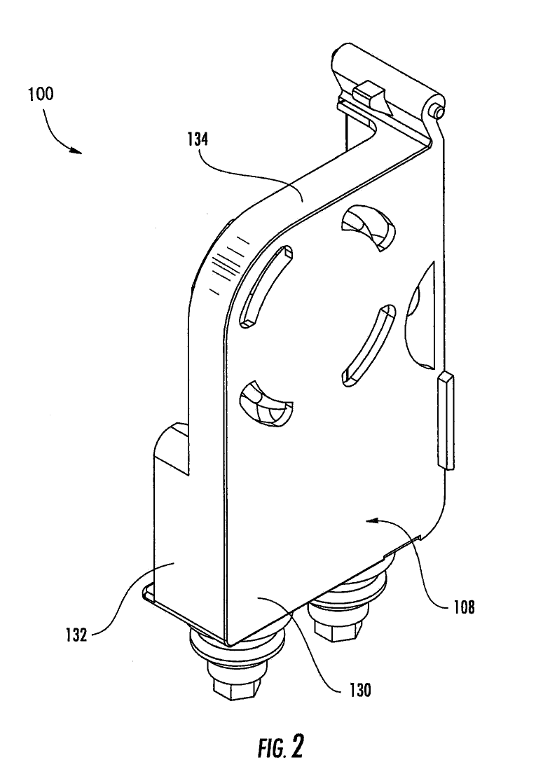

An example telecommunications module, generally indicated by the reference numeral 100 is illustrated in FIGS. 1-3. The module 100 includes a housing 102. The housing 102 has a front portion 104, a rear portion 106, a bottom portion 107 and two side portions 108 and 110. A rear wall 112 is located at the rear portion 106 of the housing 102. A bottom wall 114 is located at the bottom portion 107 of the housing 102 and is substantially perpendicular to the rear wall 112. The housing 102 is sized to fit in a bay of a docking base (including, without limitation, the docking bases 702, 802, 902, 1002 described below). The module 100 is adapted for having two telecommunications components coupled to the housing 102. A wire management device 116 is coupled to the housing 102. The housing 102 includes a connector 118 to removably couple the module 100 to the docking base.

The illustrated wire management device 116 is a radius limiting spool for storing and routing fiber optic cable without bending the cable in too tight a radius. The connector 118 is an L-shaped protrusion from the rear wall 112. The connector 118 mates with a slot, or opening, in the docking base.

The two telecommunications components are fiber optic connectors 120A, 120B (collectively, fiber optic connectors 120), sometimes referred to as opti-taps, for joining two ends of fiber optic cable. It should be understood, however, that the module 100 may include any telecommunications component(s) that will physically fit in the module 100 and may be adapted for receiving more or fewer telecommunications components. The fiber optic connectors 120 are mounted in openings in the bottom wall 114 of the housing 102 with portions of each fiber optic connector 120 within the interior space defined by the housing and portions of each fiber optic connector 120 external to the housing.

As shown in FIG. 1, fiber optic connecter 120A is coupled to a fiber optic cable tail 122. The tail 122 is used to couple the fiber optic connector 120A to a fiber optic cable (not shown) external to the module 100. The tail 122 is wrapped around the wire management device 116 and exits the housing 102 through a port 124 in the rear wall 112 of the housing 102. Although the port 124 is illustrated in this example in the rear wall 112 of the housing 102, any other suitable location may be used.

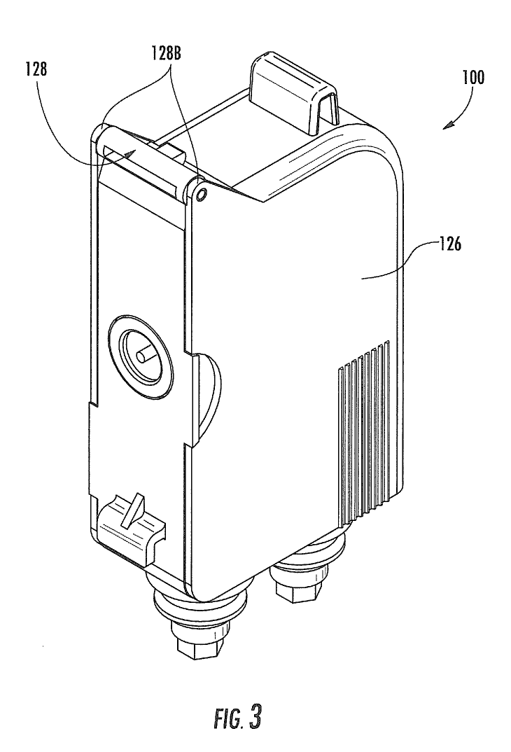

As shown in FIG. 3, the module 100 may include a cover 126. The cover 126 encloses part of the housing 102 and, together with at least part of the housing 102, defines an interior space of the module 100. In this embodiment, the cover 126 encloses the wire management device 116, an interior portion of the tail 122 and interior portions of the fiber optic connectors 120. In some embodiments, the cover may create a weather-tight interior space limiting the ability of rain, debris, dust, etc. to enter the interior space of the module 100.

The cover 126 is coupled to the housing 102 by a hinge 128. The cover 126 is operable to pivotably open and close by pivoting about the hinge 128. The hinge 128 includes a first part 128A coupled to the housing 102 and a second part 1288 coupled to the cover 126. The first part 128A and the second part 1288 may be monolithically formed parts of the housing 102 and the cover 126, respectively, or may be separately coupled to the housing 102 and/or the cover 126. Alternatively, other suitable hinges may be employed.

In this embodiment, the housing 102 also includes a side wall 130. The side wall 130 is generally perpendicular to both the bottom wall 114 and the rear wall 112. The side wall 130 is located at the side portion 108 of the housing 102, but may also, or alternatively, be located at the side portion 110. Alternatively, the side wall 130 may be centered between the side portions 108, 110.

In the particular example shown in FIGS. 1-3, the wire management device 116 is on the side wall 130. The wire management device 116 may be monolithically formed with the side wall 130, or separately formed and coupled to the side wall 130. In other embodiments, the wire management device 116 may be coupled to a different part of the module, including, for example, the rear wall, the bottom wall, etc. Additionally, or alternatively, a telecommunications component may be coupled to the side wall 130 instead of, or in addition to, the bottom wall 114.

The housing 102 includes a front wall 132 and a top wall 134. The front wall 132 is substantially perpendicular to the bottom wall 114 and the side wall 130, and substantially parallel to the rear wall 112. The top wall 134 is substantially parallel to the bottom wall 114 and substantially perpendicular to the side wall 130, the rear wall 112 and the front wall 132. In this example embodiment, the rear wall 112, the bottom wall 114, the side wall 130, the front wall 132, the top wall 134 and the cover 126 define an interior space of the module 100.

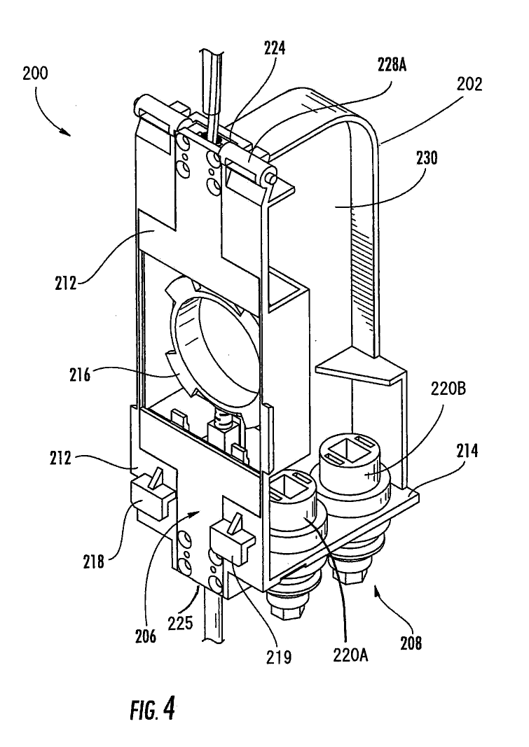

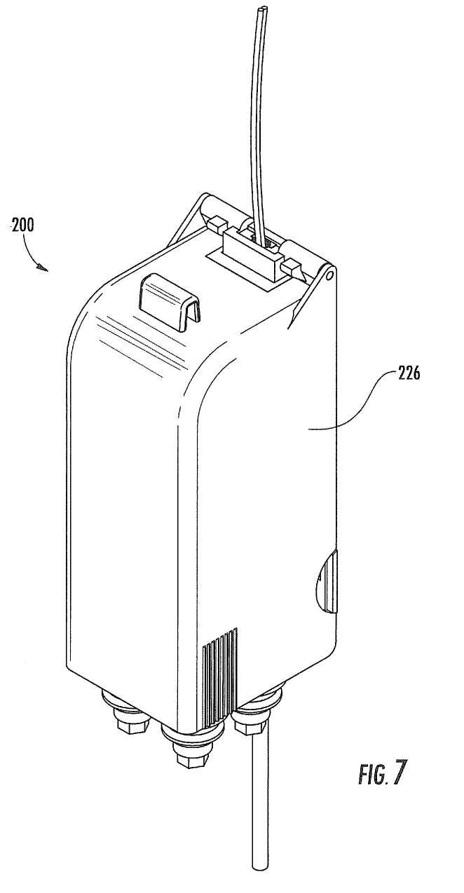

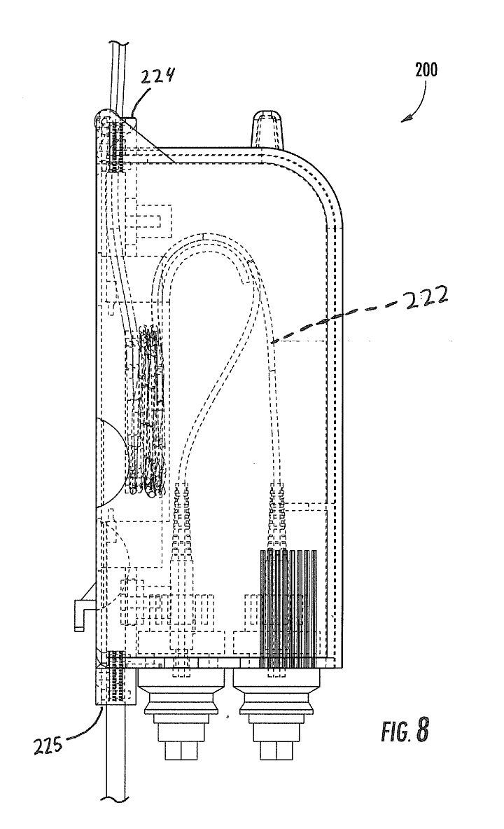

Another example telecommunications module 200 is illustrated in FIGS. 4-8. The module 200 includes a housing 202. The housing 202 has a front portion 204, a rear portion 206, and two side portions 208 and 210. A rear wall 212 is located at the rear portion 206 of the housing 202. A bottom wall 214 is located at the bottom portion 210 of the housing 202 and is substantially perpendicular to the rear wall 212.

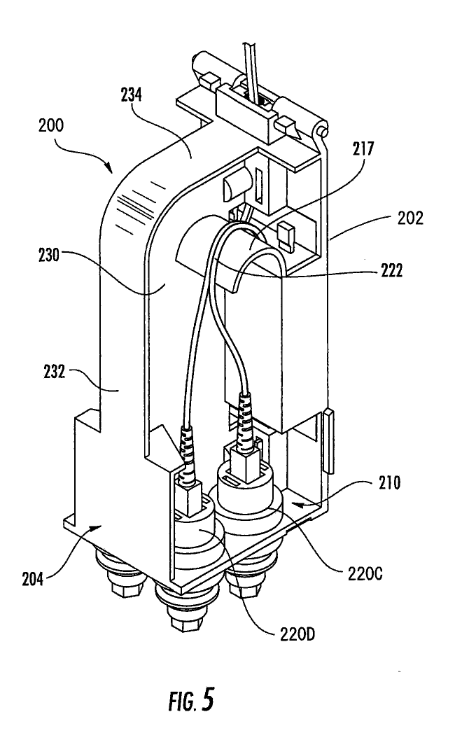

The housing 202 includes a first wire management device 216. The first wire management device 216 is positioned within a recess in the rear wall 206 of the housing 202. The illustrated wire management device 216 is a radius limiting spool for storing and routing fiber optic cable without bending the cable in too tight a radius. A second wire management device 217 can be seen in FIG. 5. The second wire management device 217 is used to guide, or route, cable within the housing, while preventing the cable from being bent too sharply.

Additionally, or alternatively, the wire management devices 216, 217 may be half moon devices, wire and/or cable clips, guides, etc.

The housing 202 is sized to fit in a bay of a docking base (such as, for example, docking bases 702, 802, 902, 1002 described below or any other suitable docking base).

The housing 202 includes two connectors 218, 219 located on the rear wall 212. The connectors 218, 219 are L-shaped protrusions from the rear wall 212, but other suitable connector(s) may be used. The connectors 218, 219 may be monolithically formed with the housing 202 or may be separately formed connectors 218, 219 coupled to the housing 202. The L-shaped connectors 218, 219 mate with complementary portions of the docking base to removably couple the module 200 to the docking base. Other types of appropriate connecters may matingly couple with the docking base in different ways.

The module 200 is adapted for having up to four telecommunications components coupled to the housing 202. The illustrated telecommunications components are fiber optic connectors 220A, 220B, 220C, 220D (collectively, fiber optic connectors 220) for joining two ends of fiber optic cable. It should be understood that the module 200 may be adapted for having more or fewer telecommunications components coupled to the housing 202 and the telecommunications component(s) may be any component(s) that will physically fit in the module 200. The fiber optic connectors 220 are mounted in openings in the bottom wall 214 of the housing 202 with portions of each fiber optic connector 220 within the interior space defined by the housing 202 and portions of each fiber optic connector 220 external to the housing 202.

As shown in FIG. 5, the fiber optic connecters 220C and 220D are coupled to a fiber optic cable tail 222. The tail 222 is used to couple the connectors 220 to a fiber optic cable external to the module 200. The tail 222 is bent over the wire management device 217, wrapped around the wire management device 216 and exits the housing 202 through a port 224 in the top portion of the housing 202. An additional port 225 is located in the bottom portion 208 of the housing 202. This port 225 may be used for ingress and/or egress of wire (e.g., fiber cable, copper wire, the tail 222, etc.) through the bottom portion 208 of the housing 202.

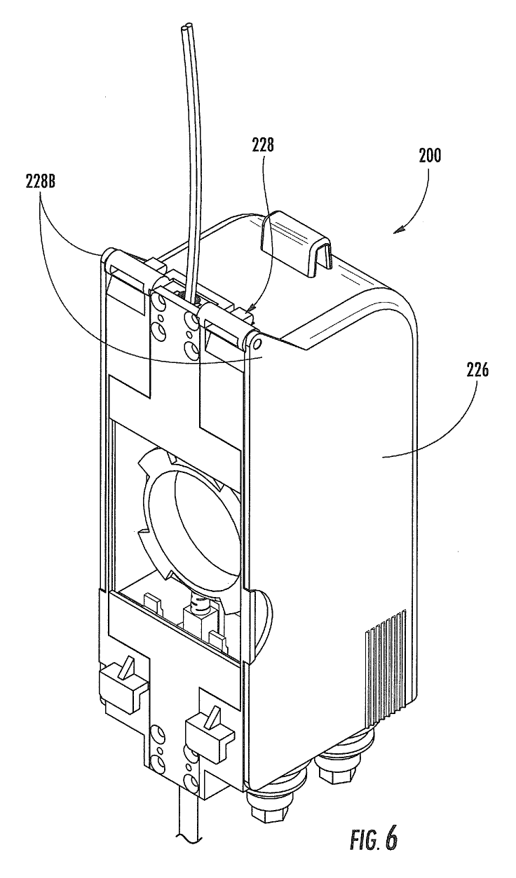

As shown in FIG. 6, the example module 200 includes a cover 226. The cover 226 encloses part of the housing 202 and, together with at least part of the housing 202, defines an interior space of the module 200. In this embodiment, the cover 226 encloses an interior portion of the tail 222 and interior portions of the fiber optic connectors 220. The cover 226 may create a weather-tight interior space limiting the ability of rain, debris, dust, etc. to enter the interior space of the module 200.

The cover 226 is coupled to the housing 202 by a hinge 228. The cover 226 is operable to pivotably open and close by pivoting about the hinge 228. The hinge 228 includes a first part 228A coupled to the housing 202 and a second part 228B coupled to the cover 226. The first part 228A and the second part 228B may be monolithically formed parts of the housing 202 and the cover 226, respectively, or may be separately coupled to the housing 202 and/or the cover 226. Alternatively, other suitable hinges may be employed.

In this example module 200, the housing 202 includes a side wall 230. The side wall 230 is generally perpendicular to both the bottom wall 214 and the rear wall 212. The side wall 230 is located approximately centered between the two side portions 208, 210 to divide the housing into two approximately equal sized chambers. Each of the two chambers may receive up to two optical fiber connectors 220 mounted therein. Alternatively, a telecommunications component may be coupled to the side wall 230 instead of, or in addition to, the bottom wall 214.

The housing 202 includes a front wall 232 and a top wall 234. The front wall 232 is substantially perpendicular to the bottom wall 214 and the side wall 230, and substantially parallel to the rear wall 212. The top wall 234 is substantially parallel to the bottom wall 214 and substantially perpendicular to the side wall 230, the rear wall 212 and the front wall 232. In this example embodiment, the rear wall 212, the bottom wall 214, the side wall 230, the front wall 232, the top wall 234 and the cover 226 define an interior space of the module 100.

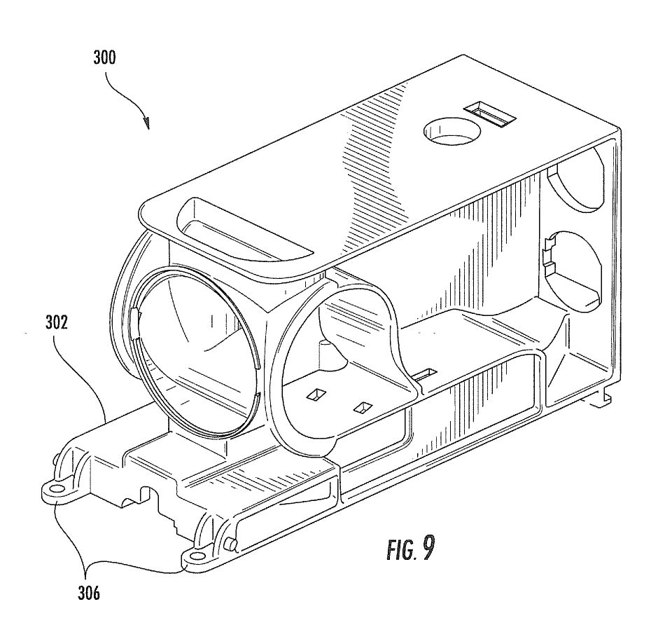

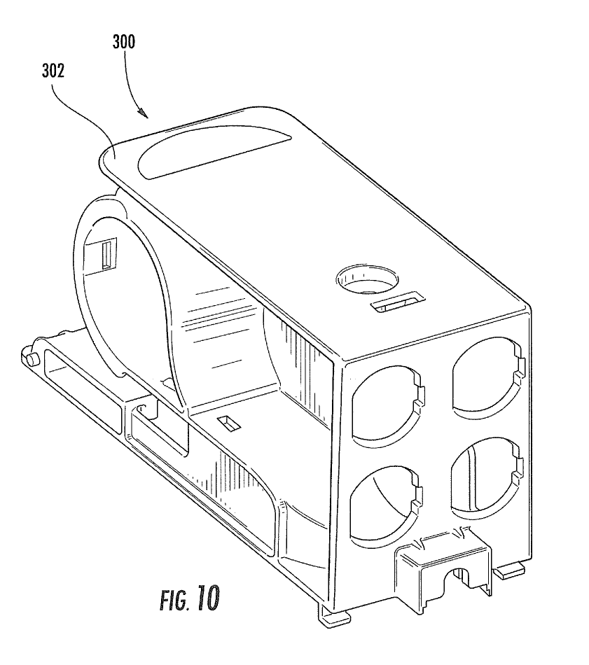

Another example telecommunications module 300, illustrated in FIGS. 9-11, includes a housing 302 and a cover 304. The module 300 is similar to module 200. For the sake of brevity, certain common features of module 300 and module 200 will not be further discussed.

The example telecommunications module 300 includes connectors 306. Connectors 306 allow the module 300 to be more permanently, or stably, affixed to a docking base with fasteners (i.e., screws, bolts, rivets, etc.) placed through the connectors 306 (as compared to mounting with only the connectors 218, 219 in module 200). The connectors 306 may be used in addition to other connecting methods and/or used instead of other connections. For example, as will be discussed below, some example docking bases include a snap catch located at the top portion of the module 100, 200, 300 that engages with the module 100, 200, 300 to retain it coupled to the docking base. Using connectors 306 with screws or the like, may, for example, decrease the stress on the snap catch, make the installation more permanent and/or make the installation of the module 300 to the docking base more stable. Additionally, if the snap catch were to break, fasteners coupled through the connectors 306 would decrease the chance that the module 300 would fall off the docking base. Furthermore, if the snap catch on the docking base breaks, the connectors 306 may be used to couple the module 300 to the docking base without requiring repair or replacement of the docking base.

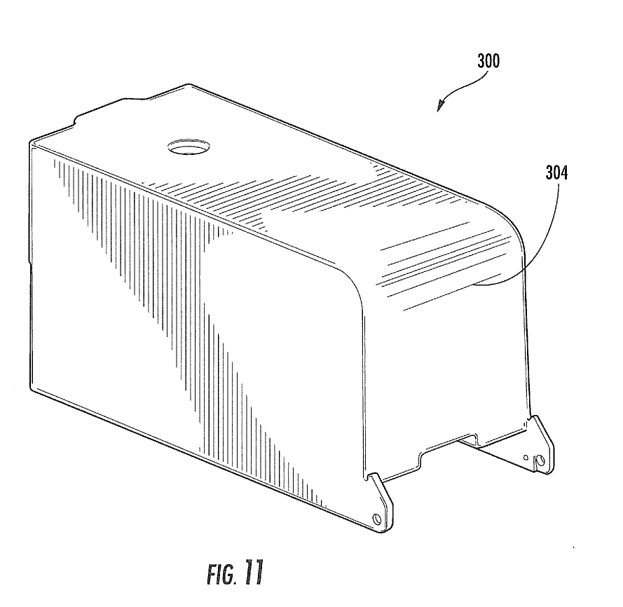

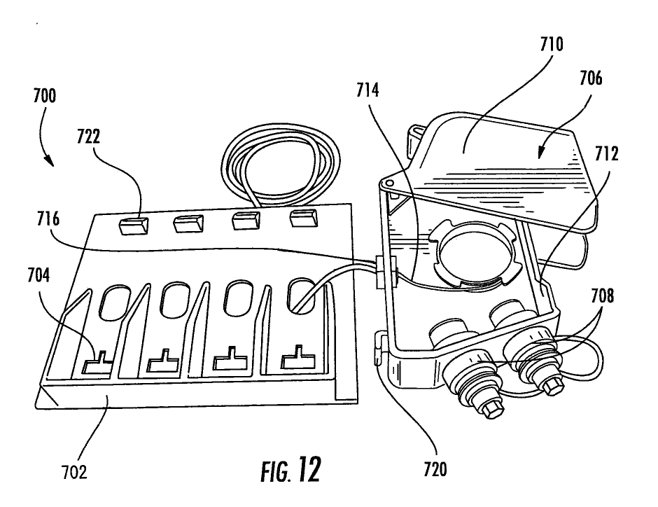

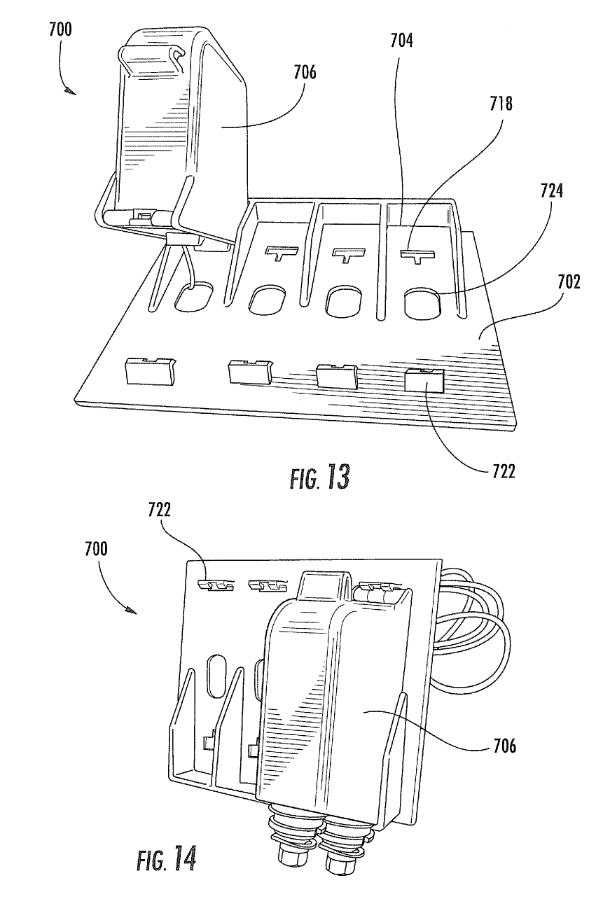

Generally the modules 100, 200, 300 are used as part of a modular system. One example modular system 700 is illustrated in FIGS. 12-14. The system 700 includes a docking base 702 having a plurality of bays 704 for receiving modules. There are four bays 704 of equal size in the example docking base 702. However, more or less (including only one) bays 704 and/or different size bays 704 (possibly including combinations of same size bays and different size bays) may be included in the docking base 704. The module may be any of the modules 100, 200, 300 discussed above, or any other suitable module. An example module 706 includes two fiber optical connectors 708 coupled within the module 706 and a cover 710 coupled to a housing 712 of the module. The cover is shown in an open position in FIG. 12 and a closed position in FIGS. 13 and 14. A tail 714 is coupled to the fiber optic connectors 708 and extends through a port 716 in the housing 712.

The docking base includes a slot 718 in each bay for receiving a connector 720 located on a bottom portion of the module 706. Additionally, a snap catch 722 is located adjacent a top portion of the module 706, and couples the module 706 to the docking base 702, when the module 706 is installed on the docking base 702. To install the module, the connector 720 is inserted into the slot 718 as shown in FIG. 13. The module is then tilted toward the docking base 702 until the rear wall of the module is adjacent the docking base 702. The top portion of the module displaces the snap catch 722 as the module 706 is being tilted toward the docking base 702. In the final position of the module 706, the snap catch 722 snaps back to its rest position around the top portion of the module 706 to retain the module 706 in position, as illustrated in FIG. 14.

The docking base 702 includes a docking port 724 in each bay 704. This docking port 724 allows wires (whether fiber optic cable, copper wire, power cables, etc.) to pass through the docking base 702 and into the module 706 (via the port 716).

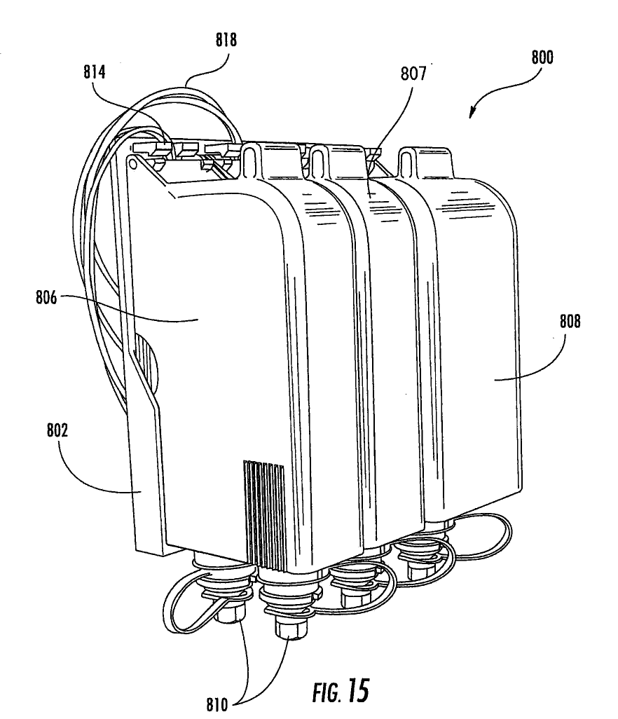

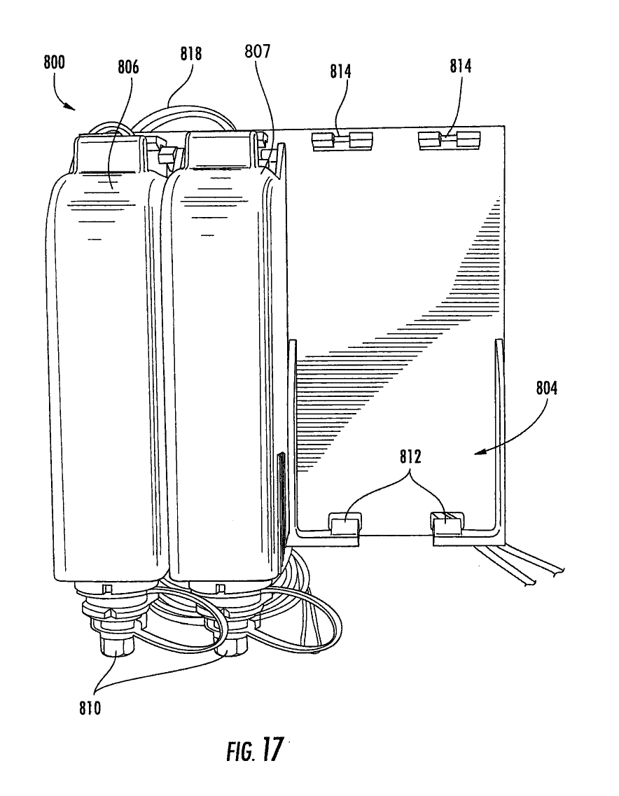

Another example system 800 is shown in FIGS. 15 to 17. The system 800 includes a docking base 802 having three bays 804 for receiving modules 806, 807, 808. As best shown in FIG. 17, the modules 806 and 807 do not have the same footprint as the module 808, and the bays 804 are accordingly not the same size. In particular, module 808 is wider than modules 806, 807. The bay 804 for module 808 is therefore wider than the bays 804 for modules 806, 807.

The modules 806, 807 and 808 may be any of the modules discussed above, or any other suitable modules. In this example, the modules 806, 807 each include two optical connectors 810, while the module 808 can include up to four optical connectors 810. Like the modules 200, 300, wires enter/exit the modules 806, 807, 808 through a port 814 in the top of each module 806, 807, 808, rather than the rear wall (as in module 100). For this reason, the docking base 802 does not include an opening similar to docking port 724 in docking base 702.

As shown in FIG. 17, the docking base 802 includes slots 812 for engaging connectors (not visible in the illustrations) on a rear wall of the modules 806, 807, 808. Additionally, each bay 804 includes a snap catch 814 along a top portion of the bay 804 for engaging a top portion of the module 806, 807, 808 to retain the module 806, 807, 808 coupled to the docking base 802.

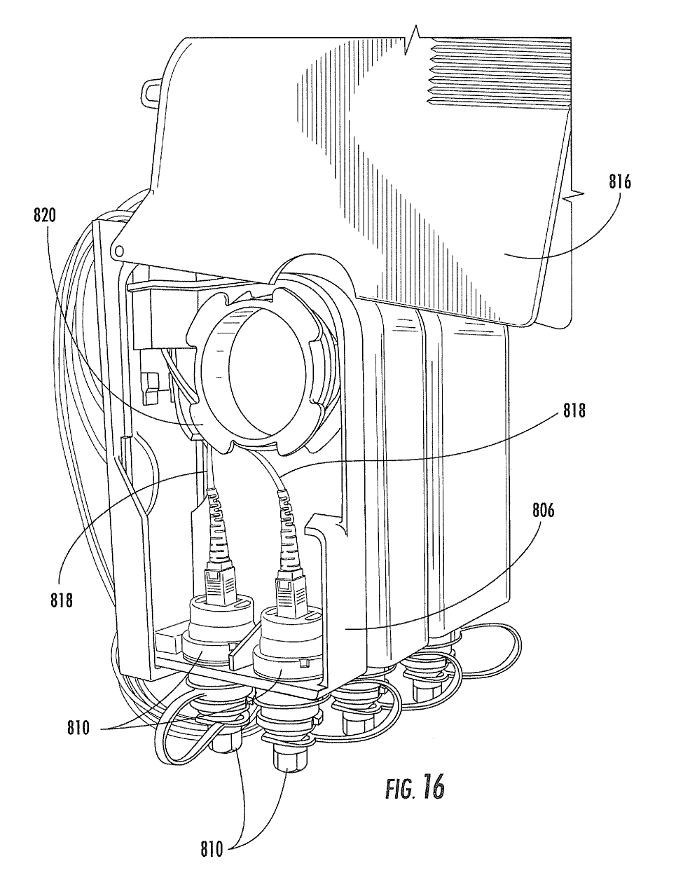

In FIG. 16, the module 806 is illustrated with its cover 816 in an open position. Inside the module, tails 818 are coupled to the optical fiber connecters 810. The tails 818 are wound around a wire routing element 820 and out the port 814 in the top of the module 806.

Another example system 900 is shown in FIGS. 18 to 20. The system includes a docking base 902 having a front 904, a back 908 and four sides 906 defining an interior space. The back 908 of the docking base 902 is structured for attachment to a generally flat surface. The docking base 902 includes a port 910 for passing telecommunications wire 912 (e.g., fiber optic cable, copper wire, power cables, coax cable, etc.) between an exterior of the docking base 902 and the interior space. The docking base 902 also includes two bays 914 on the front 904 of the docking base 902. The bays 914 are oriented to open away from the interior space of the docking base 902. The bays 914 are adapted to receive a telecommunications module 916.

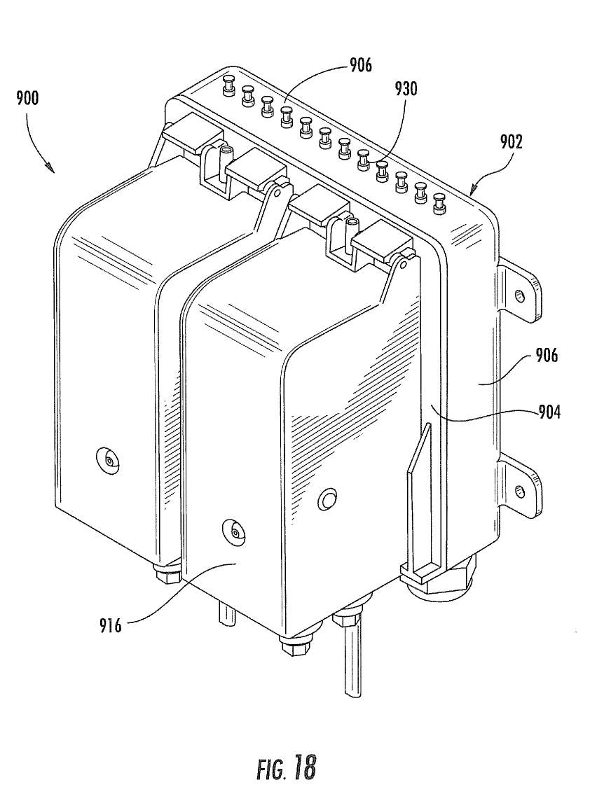

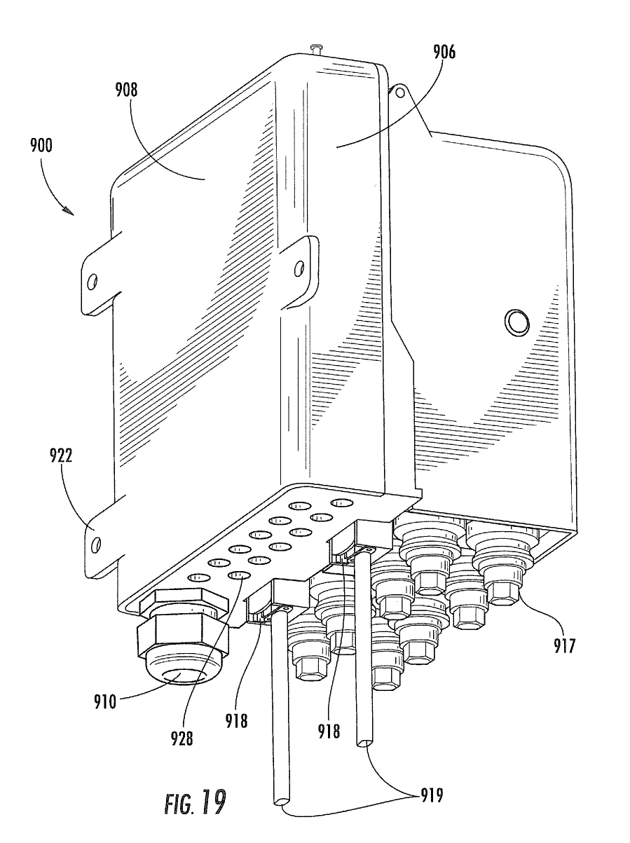

The modules 916 may be any of the modules discussed above, or any other suitable module. In the example system 900 of FIGS. 18-20, the modules 916 are similar to module 200. Each module 916 includes four optical fiber connectors 917. Ports 918 permit wire (e.g., power wire, copper wire, fiber optic cable, fiber optic tails 919, etc.) to pass into the modules 916. As can best be seen in FIGS. 19 and 20, a notch 920 in the docking base 902 receives the ports 918.

The back 908 of the docking base 902 is adapted to be mounted to a generally flat surface. The dock includes three mounting tabs (also referred to as connectors) 922. By use of suitable fasteners (e.g., screws, bolts, rivets, etc.) through the holes in these tabs 922, the docking base 902 may be semi-permanently coupled to almost any flat surface, such as a wall, a cabinet, a pedestal, etc.

As shown in FIG. 20, the example docking base 902 is a multipart docking base 902. The docking base 902 includes a face portion 924 and a housing portion 926. The housing portion 926 includes the back 908 of the docking base 902 and the four sides 906 of the docking base 902. The face portion 924 is adapted for removable mounting (such as, for example, by screws, bolts, interlocking tabs, etc.) to the housing portion 926.

Because of the multipart construction of the docking base 902, the face portion 924 may be removed to access the interior portion of the docking base 902 (defined by the back 908 and the sides 906). Within the interior portion, other telecommunications components, wires, cables, etc. may be located. Thus for example, a wire may enter the interior portion of the docking base 902 through the docking port 910 or through the additional ports 928. The wire may be coupled to telecommunications components housed in the interior portion. For example, the wire may terminate to a copper terminal block with terminals 930 protruding from the housing portion 926. Thus, the system may include both fiber optic connectivity (housed in the modules 916) and copper connectivity (housed within the interior portion of the docking base 902). Other combinations of copper, fiber, power, etc. may also be accomplished with the system.

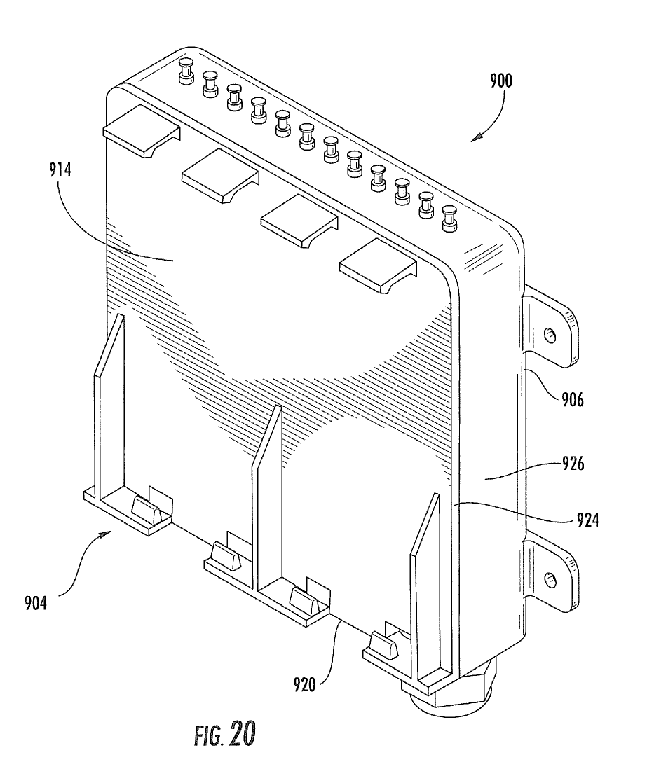

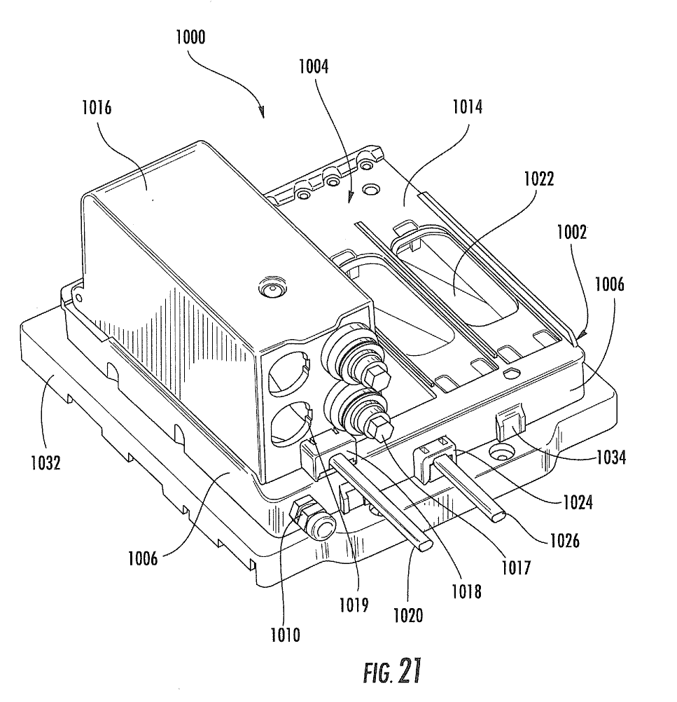

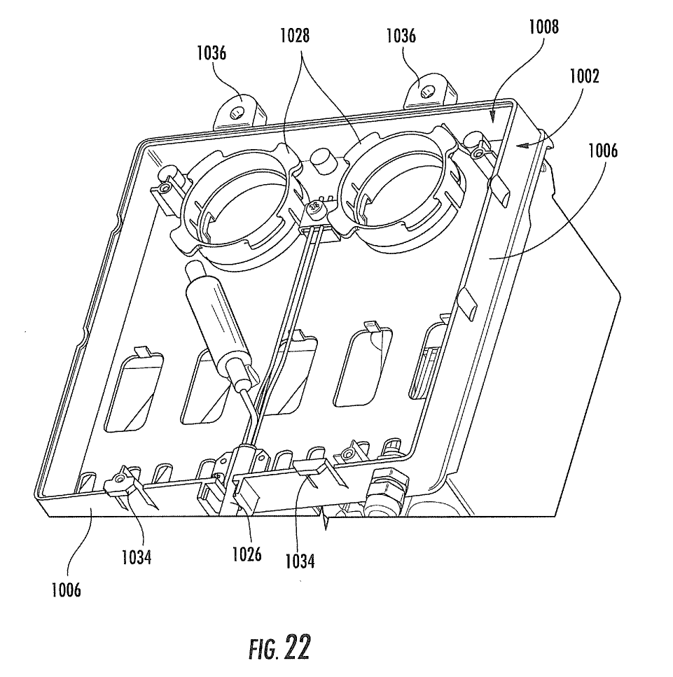

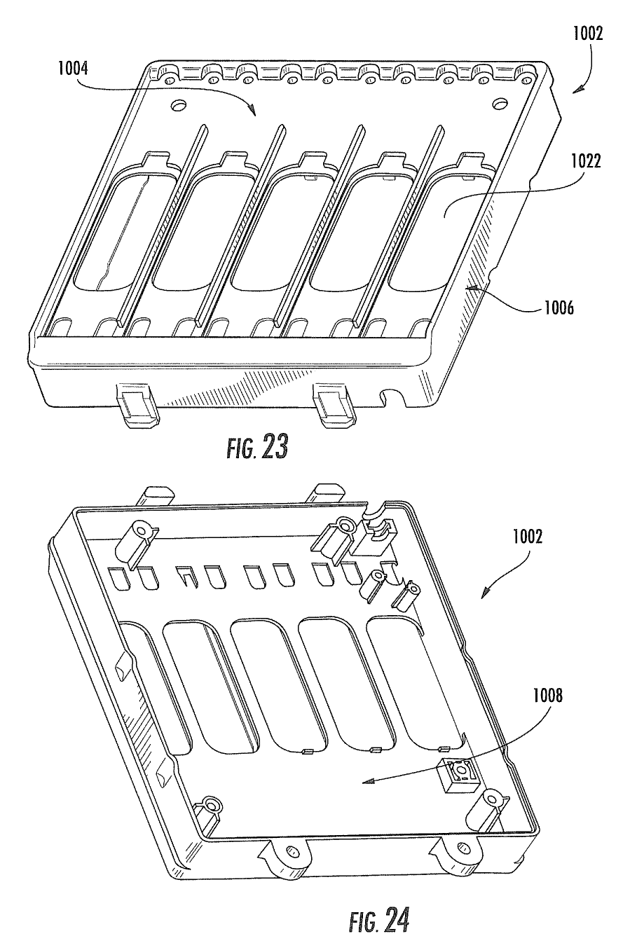

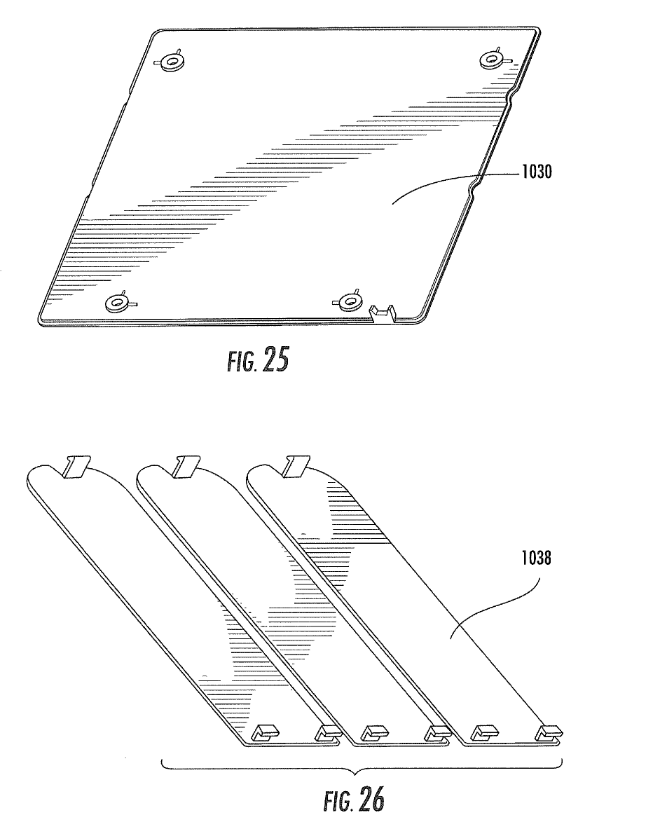

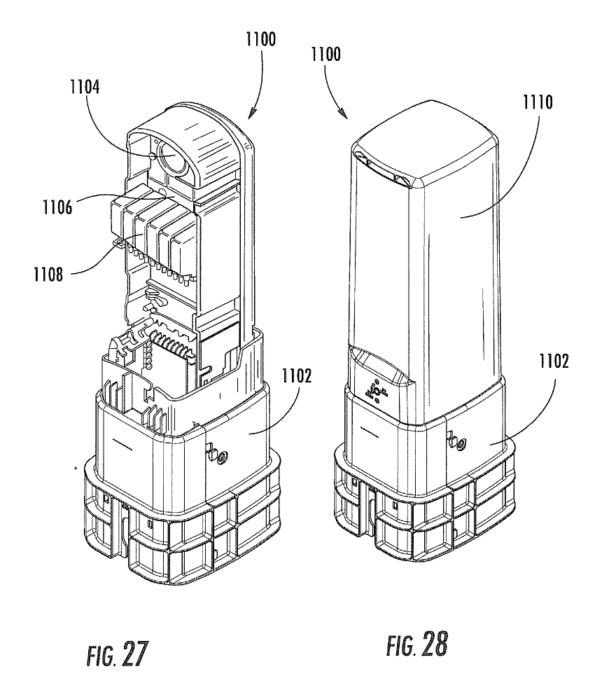

Another example system 1000 is shown in FIGS. 21-26. The system 1000 includes a docking base 1002 having a front 1004, a back 1008 and four sides 1006 defining an interior space. The back 1008 of the docking base 1002 is structured for attachment to a generally flat surface. The docking base 1002 includes a port 1010 for passing wire (e.g., fiber optic cable, copper wire, power cables, coax cable, etc.) between an exterior of the docking base 1002 and the interior space. The docking base 1002 also includes bays 1014 on the front 1004 of the docking base 1002. The bays 1014 are oriented to open away from the interior space of the docking base 1002. The bays 1014 are adapted to receive a telecommunications module 1016.

The module 1016 may be any of the modules discussed above or any other suitable modules. In the example system 1000 of FIGS. 21-26, the module 1016 is similar to module 300. The module 1016 is illustrated including two optical fiber connectors 1017 coupled within the modules 1016 and two holes 1019 into which two additional optical fiber connectors 1017 may be mounted. Ports 1018 permit wire (e.g., copper wire, power wire, fiber optic cable, tails 1020, etc.) to pass into the module 1016.

Each bay 1014 of the docking base 1002 includes at least one docking port 1022. The docking port 1022 permits wire to pass between the interior space and the exterior of the docking base 1002. When modules 1016 are coupled to the bays 1014, this permits wire to be passed from the interior space into the module 1016.

The docking base 1002 includes an additional port 1024 for permitting wire to pass outside of the docking base to the internal space. This wire 1026 may be of the same type as that coupled to the modules or a different type. For example, the cable 1020 is fiber optic cable. The wire 1026 may be fiber, copper wire, power lines, etc. Similarly wire passed through port 1010 may be any type of telecommunications wire regardless of other types used with the system.

Within the interior portion, other telecommunications components, wires, etc. may be located. The interior space of the docking base 1002 can also include wire management devices, such as spools 1028, for routing and storing wire contained in the interior space of the docking base 1002. A rear cover 1030 may be attached to the docking base 1002 to enclose the interior portion and any wire or components contained therein.

The system 1000 may include a mounting plate 1032 to which docking base 1002 may be coupled. The mounting plate may be mounted to a wall, cabinet, pedestal, etc. and the docking base 1002 mounted to the mounting plate using tabs 1034 and screws, bolts, rivets, etc. through tabs 1036.

Covers 1038 may be used to cover the docking port 1022 of any bay 1014 which does not have a module 1016 mounted therein, or through which the interior space need not be accessed.

The modules and systems discussed above may be used inside or outside any suitable enclosure (e.g., a pedestal, cabinet, etc) or without an enclosure (e.g., mounted on a wall, mounted on a pole, etc.).

According to another aspect of the present disclosure, a telecommunications pedestal assembly includes a pedestal mounting plate for receiving telecommunications distribution components, a docking base coupled to the mounting plate, the docking base having at least one bay, the bay adapted for receiving a telecommunications module and a telecommunications module removably coupled to the docking base. The module has a housing and at least one telecommunications component coupled to the housing. The housing is sized to fit in the bay of the docking base and adapted for having at least one telecommunications component coupled to the housing. The housing includes at least one port for allowing cable to pass through the housing and at least one connector for removably coupling the module to the docking base.

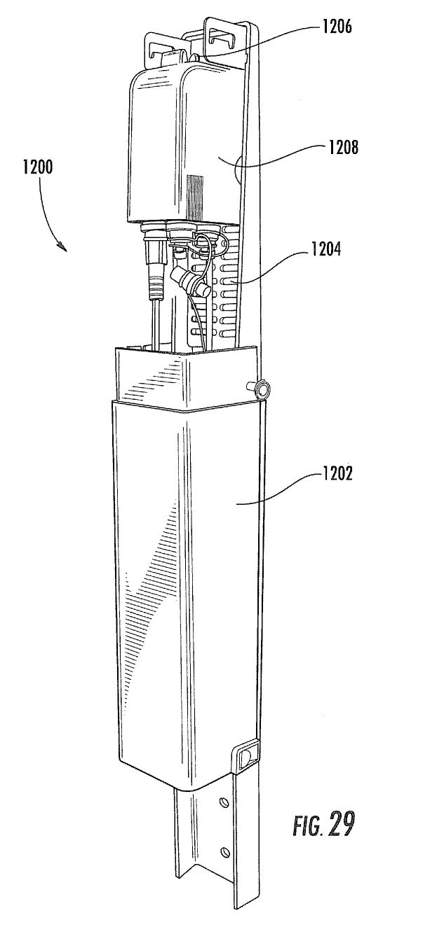

One such telecommunications pedestal 1100 is shown in FIGS. 27 and 28. The pedestal 1100 includes a base 1102 and a pedestal mounting plate 1104. A docking base 1106 is mounted to the pedestal mounting plate 1104. The docking base 1106 may be any of the docking bases discussed above or any other suitable docking base. The pedestal includes six modules 1108 coupled to the docking base 1106. The modules 1108 may be any of the modules discussed above or any other suitable modules. As shown in FIG. 28, a cover 1110 may be mounted on the base 1102 to enclose the pedestal mounting plate 1104, the docking base 1106 and the modules 1108.

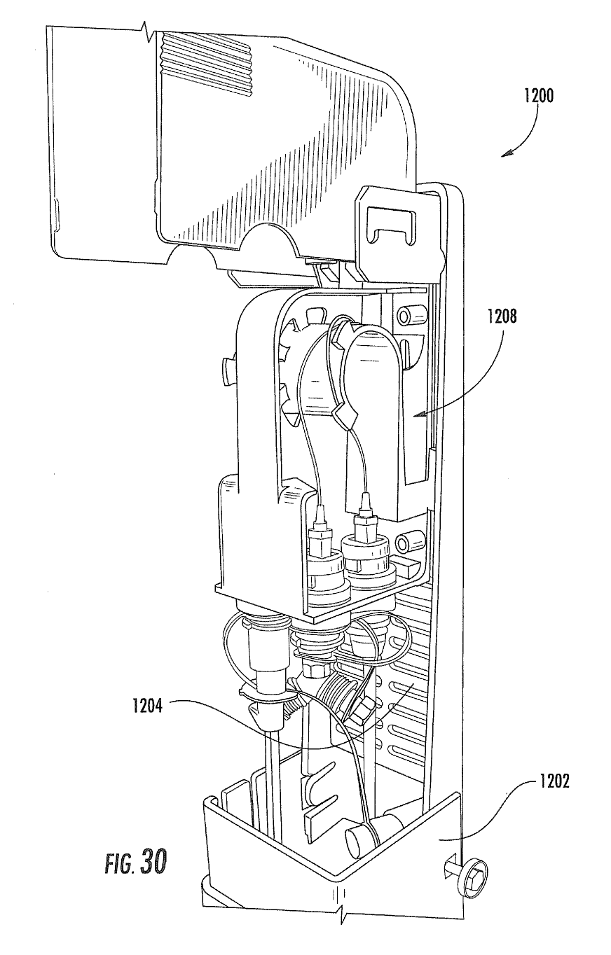

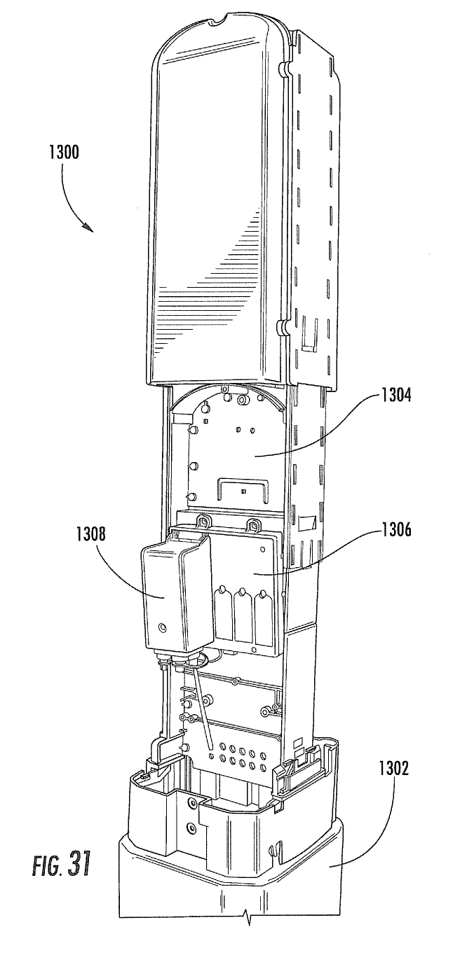

Another such telecommunications pedestal assembly 1200 is shown in FIGS. 29 and 30. The pedestal 1200 includes a base 1202 and a pedestal mounting plate 1204. A docking base 1206 is mounted to the pedestal mounting plate 1204. The docking base may be any of the docking bases discussed above or any other suitable docking base. The pedestal includes a module 1208 coupled to the docking base 1206. The modules 1208 may be any of the modules discussed above or any other suitable modules.

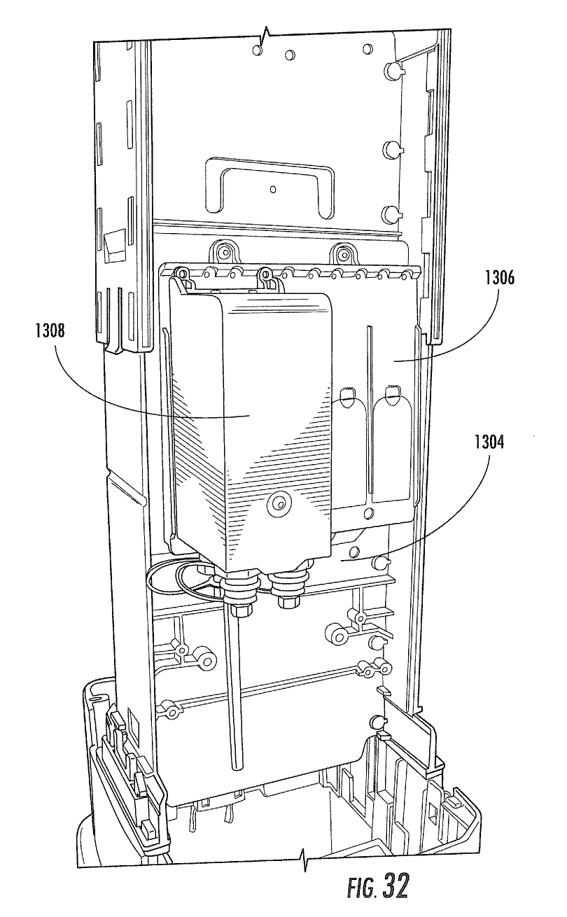

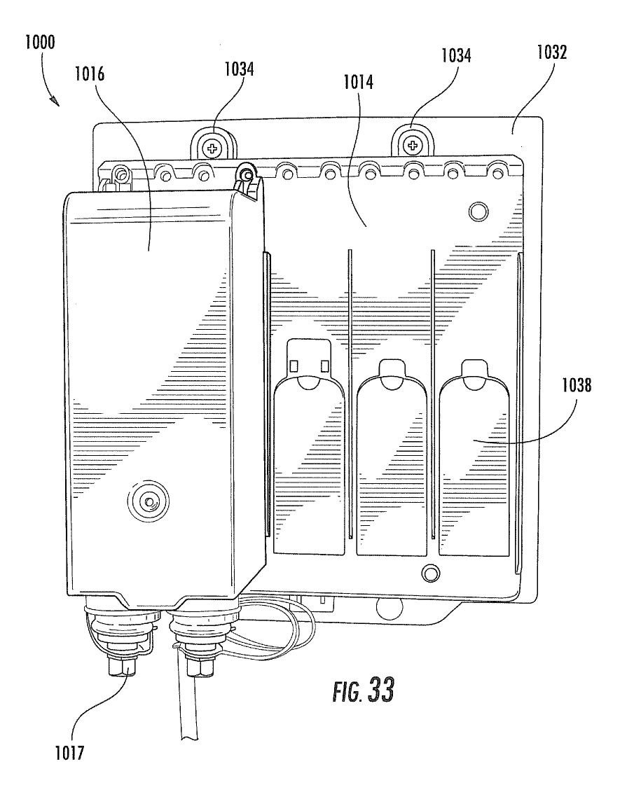

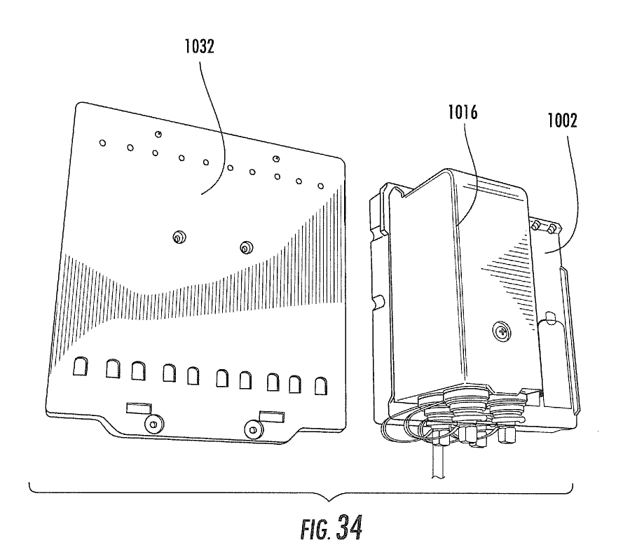

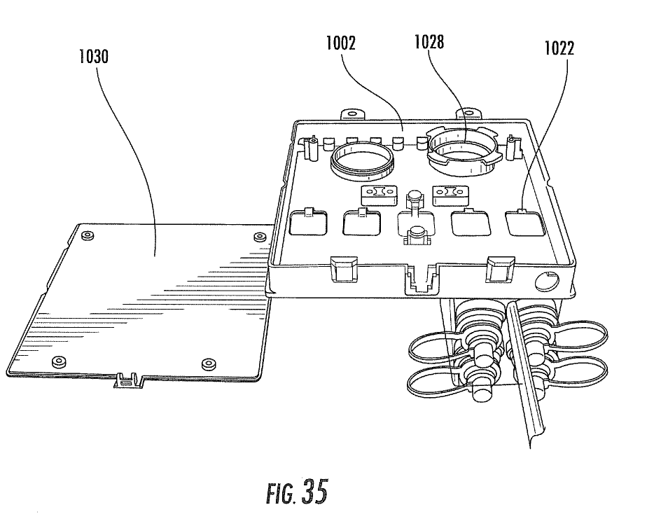

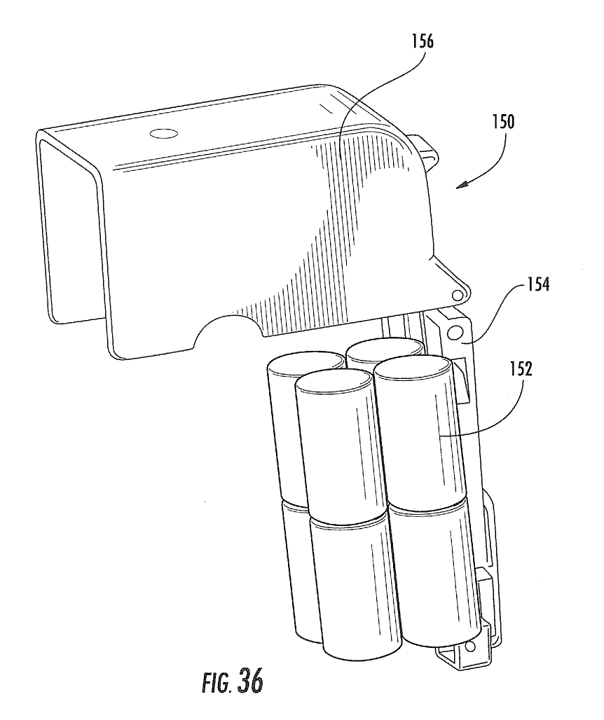

Yet another example telecommunications pedestal assembly 1300 is shown in FIGS. 31-32. The pedestal 1300 includes a base 1302 and a pedestal mounting plate 1304. A docking base 1306 is mounted to the pedestal mounting plate 1304. The docking base 1302 may be any of the docking bases discussed above or any other suitable docking base. The pedestal includes a module 1308 coupled to the docking base 1306. The modules 1208 may be any of the modules discussed above or any other suitable modules.

As can be seen, the modules, docking bases, systems and pedestals discussed herein, create a versatile and scalable system. For example, a pedestal may be installed with only one module and additional modules to be added later as needed. Additionally, or alternatively, a single module may not be fully populated, as illustrated, for example, by module 1016 in FIG. 21. When additional optical fiber connectors 1017 are needed, an additional optical fiber connector 1017 may be installed in the module 1016. Furthermore, the modules in a system do not necessarily all include the same telecommunications components. Thus, a single docking bay may be populated with modules for different telecommunications purposes. For example, a docking base may include modules for both fiber connectivity and copper connectivity.

An example of the versatility and scalability of the modules and systems disclosed herein will now be provided. In a neighborhood with eight houses and copper wire service provided to each house, a single pedestal assembly according to the present disclosure (such as pedestal 1300) may be installed. One or more modules containing copper connection components can be coupled to the docking base and appropriate connections made to each home in the neighborhood. If and when service(s) using fiber optic cables are available to the neighborhood, a module with fiber optic connectivity (such as optical fiber connectors, etc.) may be added to the pedestal. The fiber connectivity modules may coexist with the copper connectivity modules, or may replace the copper modules, depending on the circumstances. If only two of the homes initially are to be connected to the fiber optic services, a module (such as 1016) may be installed in the pedestal. If and when the next two homes are to be connected to the fiber services, additional fiber optic connectors may be purchased and installed in the module. If and when the remaining four homes in the neighborhood are to be connected to the fiber service, an additional module (whether fully or partially populated) may be installed.

Modules may be provided fully assembled and populated with components, or without any telecommunications components, or as a kit, etc. A telecommunications module kit for assembly by a user may include a telecommunications module (as discussed above) for removable coupling to a docking base. The kit may include a telecommunications component for coupling to the module housing.

The foregoing description of the embodiments has been provided for purposes of illustration and description. It is not intended to be exhaustive or to limit the invention. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the invention, and all such modifications are intended to be included within the scope of the invention.

1. A telecommunications module for mounting to a docking base having at least one bay, the bay adapted for receiving a module, the module comprising:
a housing having a front portion, a rear portion, a bottom portion, a top portion, and two side portions, the housing including a rear wall located at the rear portion of the housing and a bottom wall substantially perpendicular to the rear wall located at the bottom portion of the housing, the housing sized to fit in the bay of the docking base and adapted for having at least one telecommunications component coupled to the housing, the housing including at least one wire management device, at least one port for allowing wire to pass through the housing, and at least one connector for removably coupling the module to the docking base.

2. The module of claim 1 wherein the telecommunications component is an optical fiber connector and the housing includes at least one mounting hole for receiving the optical fiber connector.

3. The module of claim 2 wherein the housing is constructed to retain the optical fiber connector in the mounting hole with a first part of the optical fiber connecter inside the housing and second part of the optical fiber connector outside the housing.

4. The module of claim 2 further comprising at least one optical fiber connector installed in the housing.

5. The module of claim 4 further comprising a tail coupled to the optical fiber connecter for coupling the optical fiber connector to an optical fiber.

6. The module of claim 1 further comprising at least one side wall substantially perpendicular to both the bottom wall and the rear wall.

7. The module of claim 6 wherein the wire management device is coupled to the side wall.

8. The module of claim 7 wherein the wire management device is monolithically formed with the side wall.

9. The module of claim 6 wherein the side wall is positioned approximately centered between the two side portions to divide the housing into two substantially equal sized chambers.

10. The module of claim 1 wherein the wire management device is coupled to the rear wall.

11. The module of claim 1 further comprising a cover coupled to the housing, the cover and at least part of the housing combining to define an interior space of the module.

12. A telecommunications pedestal comprising:
a pedestal mounting plate for receiving telecommunications distribution components;
a docking base coupled to the mounting plate, the docking base having at least one bay, the bay adapted for receiving a telecommunications module;
a telecommunications module removably coupled to the docking base, the module having a housing and at least one wire management device coupled to the housing, the housing sized to fit in the bay of the docking base and adapted for having at least one telecommunications component coupled to the housing, the housing including at least one port for allowing wire pass through the housing, and at least one connector for removably coupling the module to the docking base.

13. The pedestal of claim 12 wherein the docking base is a monolithically formed part of the pedestal mounting plate.

14. The pedestal of claim 12 wherein the telecommunications module includes a cover coupled to the housing.

15. The pedestal of claim 12 wherein the telecommunications component is an optical fiber connector and the housing includes at least one mounting hole for receiving the optical fiber connector.

16. The pedestal of claim 15 wherein the optical fiber connector extends substantially vertically through a bottom wall of the module housing.

17. The pedestal of claim 12 further comprising a pedestal base for supporting the pedestal mounting plate, the docking base and the module.

18. The pedestal of claim 12 further comprising an additional telecommunications module removably coupled to the docking base, the additional module adapted for having an additional telecommunications component coupled to the housing, and wherein the additional telecommunications component is not of the same type as the telecommunications component for which the telecommunications module is adapted.

19-27. (canceled)

28. A telecommunications module kit for assembly by a user, the kit comprising:
a telecommunications module for removable coupling to a docking base, the module having a housing and at least one wire management device coupled to the housing, the housing sized to fit in the bay of the docking base and adapted for having at least one telecommunications component coupled to the housing, the housing including at least one port for allowing wire to pass through the housing, and at least one connector for removably coupling the module to the docking base; and
a telecommunications component for coupling to the module housing.

29. The kit of claim 28 further comprising a docking base having at least one bay, the bay adapted for receiving the module.
